(19) United States
(12) Patent Application Publication
(10) Pub. No.: US 2001/0002707 A1
(43) Pub. Date: Jun. 7, 2001

(54) Apparatus and method for simulating MOSFET

(76) Inventor: Shigetaka Kumashiro, Tokyo (JP)

Correspondence Address: SUGHRUE, MION, ZINN,, MACPEAK & SEAS, 2100 Pennsylvania Avenue, N.W., Washington, DC, 20037, US

(21) Appl. No.: 09/726,114

(22) Filed: Nov. 30, 2000

(30) Foreign Application Priority Data
Dec. 1, 1999 (JP) 341672/1999

(51) Int. Cl. H01L 29/76; H01L 29/94

(52) U.S. Cl. 257/288; 257/368; 257/410; 257/411

(57) ABSTRACT

A MOSFET simulation apparatus includes an output unit, and a processor which simulates an operation of MOSFET using a new MOSFET model, and outputs the simulation result to the output unit. The new MOSFET model includes a MOSFET model, a first circuit model and a second circuit model. The MOSFET model is known as BSIM3V3 and has a gate, a source, a drain and a gate insulating film. The first circuit model is connected between the gate and the source, and includes first and second diode models connected in parallel in opposite directions to each other. The second circuit model connected between the gate and the drain, and including third and fourth diode models connected in parallel in opposite directions to each other.

### BACKGROUND OF THE INVENTION

1. Field of the Invention

The present invention relates to an apparatus and method of simulating a MOSFET using a simulation model of a MOS type field effect transistor (MOSFET).

2. Description of the Related Art

Conventionally, as the model for standard circuit simulation of a MOSFET, there is known BSIM3V3 described in “A Physical and Scalable I-V Model in BSIM3V3 for Analog/Digital Circuit Simulation” (IEEE Transactions on Electron Devices, vol.44, No.2, pp.277-287, 1997) by Y. Cheng, M-C. Jeng, Z. Liu, J. Huang, M. Ghan, K. Chen, P. Ko, and C. Hu, for example. However, it is not assumed that the situation that a gate oxide film has the film thickness equal to or less than 2 nm, when these models developed. Therefore, a gate oxide film tunnel leak current is not modeled.

On the other hand, the modeling of a gate oxide film tunnel current itself in the MOS diode structure is carried out from old days. In recent days, an analysis equation model is described in “Modeled Tunnel Currents for High Dielectric Constant Dielectrics” (IEEE Transactionson Electron Devices, vol.45, No.6, pp.1350-1355, 1998) by E. Vogel, K. Ahmed, B. Hornung, W. Henson, P. McLarty, G. Lucovsky, R. Hauser, and J. Wortman, for example. However, these models are one-dimensional structure model uniform in a direction. Therefore, the model cannot correspond to the MOSFET structure which has a source and a drain.

The gate oxide film tunnel current is conspicuous in the film thickness of a gate oxide film equal to or less than 2 nm. However, in the above-mentioned models, it is difficult to simulate a gate oxide film tunnel current between the gate and the source and between the gate the drain in the MOSFET. Especially, it is difficult to realize a model to simulate the tunnel current in the model in which the asymmetry of the gate length dependence which exists in the tunnel current of the MOSFET, or a transient characteristic and temperature non-dependence can be reproduced.

In conjunction with the above description, a method of calculating a series resistance in a FET is disclosed in Japanese Laid Open Patent Application (JP-A-Heisei 7-202219). In this reference, a mutual conductance gm (2) is calculated from a relation (1) of drain current Ids of the FET measured in an actual use state and voltage Vgs between the gate and the source. The high function (3) obtained by plotting the values of 1/gm with respect to 1/(Ids)^{½} is approximated to the primary function (6). A conductance constant K is obtained from the tangent (n/m) of the primary function and a source series resistance Rs is obtained from the intercept.

Also, a reliability simulation method of a semiconductor integrated circuit is disclosed in Japanese Laid Open Patent Application (JP-A-Heisei 11-97676). In this reference, a hot carrier stress direction is determined based on which of a source terminal and a drain terminal is higher in voltage, when substrate current or gate current with respect to a MOSFET of the semiconductor integrated circuit is maximum. A simulation time is divided in a period during which the MOSFET is in a forward direction state and a period during which the MOSFET is in an inverse direction. A SPICE parameter table for the post-degradation forward direction state or the post-degradation inverse direction state is referred to in each of the periods so as to generate post-degradation SPICE parameter. An post-degradation operation waveform is calculated using the post-degradation SPICE parameter.

Also, an apparatus for analyzing a field effect type transistor is disclosed in Japanese Patent No. 2,803,543. In this reference, the field effect type transistor is formed on an SOI substrate. Electric field near an gate oxide film which is derived from a two-dimensional electric field distribution from a drain electrode is approximated by a one-dimensional potential distribution formed between two electrodes; one being a gate electrode and the other being a virtual electrode provided on a location beneath the gate electrode. The characteristics and electric quantities of the transistor are calculated by a one-dimensional solution method which uses the one-dimensional potential distribution.

Also, a method of analyzing a field effect type transistor is disclosed in Japanese Patent No. 2,962,346. In this reference, a semiconductor layer is formed on an insulator. The volume of an region where the carrier of a conductive type which is different from that of carriers in a channel region are accumulated in the semiconductor layer is previously calculated. The difference the carrier generation quantity and carrier extinct quantity during a time step t1 is added to a carrier quantity to calculate a carrier quantity after the time step t1. The carrier quantity after the time step t1 is divided by the volume of the accumulation region to calculate a hole density after the time step t1 . A carrier extinct quantity due to recombination and diffusion per a unit time is newly calculated based on the hole density after the time step t1 . The calculation of the carrier quantity and hole density for the next time step is repeated. A transition change of a conductive current is calculated which is brought about by the transient change of a total carrier amount or density.

### SUMMARY OF THE INVENTION

Therefore, an object of the present invention is to provide an apparatus and method for simulating the operation of a MOSFET.

Another object of the present invention is to provide an apparatus and method for simulating the operation of a MOSFET using a gate oxide film tunnel current model of a MOSFET.

Still another object of the present invention is to provide an apparatus and method for simulating the operation of a MOSFET in which a transient characteristic and temperature non-dependence can be reproduced.

In order to achieve an aspect of the present invention, a MOSFET simulation apparatus includes an output unit, and a processor which simulates an operation of MOSFET using a new MOSFET model, and outputs the simulation result to the output unit. The new MOSFET model includes a MOSFET model, a first circuit model and a second circuit model. The MOSFET model is known as BSIM3V3 and has a gate, a source, a drain and a gate insulating film. The first circuit model is connected between the gate and the source, and includes first and second diode models connected in parallel in opposite directions to each other. The second circuit model connected between the gate and the drain, and including third and fourth diode models connected in parallel in opposite directions to each other.

It is desirable that the gate insulating film is equal to or thinner than 2 nm.

Also, it is desirable that each of the first to fourth diode models does not depend on temperature. In this case, each of the first to fourth diode models may include a resistance model and a voltage controlled current source without a capacitance model. In this case, the voltage controlled current source may be expressed by

$$i = Is [ exp ( \frac{V}{{N}_{FT}} ) - 1 ]$$

where i is current, N_{FT} is a bias-dependence parameter of tunnel current, V is a voltage applied to the voltage controlled current source, and Is is source current.

Also, the first diode model has an anode connected to the gate and a cathode connected to the source and the third diode models has an anode connected to the gate and a cathode connected to the drain, and the first and third diode models may be used when a voltage of the gate is higher than voltages of the source and the drain, respectively. In this case, it is desirable that each of the first and third diode models has an area equal to a half of an area of the gate.

Also, the second diode model has an anode connected to the source and a cathode connected to the gate and the fourth diode models has an anode connected to the drain and a cathode connected to the gate, and the second and fourth diode models may be used when a voltage of the gate is lower than voltages of the source and the drain, respectively. In this case, the second diode model may have an area equal to an overlapping area of the gate and the source, and the fourth diode model may have an area equal to an overlapping area of the gate and the drain.

In order to achieve another aspect of the present invention, a recording medium in which a program is recorded for a MOSFET simulation method using a new MOSFET model. The new MOSFET model includes a MOSFET model, a first circuit model and a second circuit model. The MOSFET model is known as BSIM3V3 and has a gate, a source, a drain and a gate insulating film. The first circuit model is connected between the gate and the source, and includes first and second diode models connected in parallel in opposite directions to each other. The second circuit is connected between the gate and the drain, and includes third and fourth diode models connected in parallel in opposite directions to each other.

Here, it is desirable that the gate insulating film is equal to or thinner than 2 nm.

Also, it is desirable that each of the first to fourth diode models does not depend on temperature. In this case, each of the first to fourth diode models includes a resistance model and a voltage controlled current source without a capacitance model. In this case, the voltage controlled current source is expressed by

$$i = Is [ exp ( \frac{V}{{N}_{FT}} ) - 1 ]$$

where i is current, N_{FT} is a bias-dependence parameter of tunnel current, V is a voltage applied to the voltage controlled current source, and Is is source current.

Also, the first diode model has an anode connected to the gate and a cathode connected to the source and the third diode models has an anode connected to the gate and a cathode connected to the drain, and the first and third diode models are used when a voltage of the gate is higher than voltages of the source and the drain, respectively. In this case, each of the first and third diode models may have an area equal to a half of an area of the gate.

Also, the second diode model has an anode connected to the source and a cathode connected to the gate and the fourth diode models has an anode connected to the drain and a cathode connected to the gate, and the second and fourth diode models may be used when a voltage of the gate is lower than voltages of the source and the drain, respectively. In this case, the second diode model may have an area equal to an overlapping area of the gate and the source, and the fourth diode model has an area equal to an overlapping area of the gate and the drain.

In order to achieve still another aspect of the present invention, a MOSFET simulation method using a new MOSFET model, is attained by when a voltage of a gate of a MOSFET model known as BSIM3V3 is higher than voltages of a source and drain, respectively, simulating a gate insulating film tunnel current using a first model having no temperature dependency provided between the gate and a source and a second model having no temperature dependency provided between the gate and a drain; and by when the voltage of the gate is lower than the voltages of the source and drain, respectively, simulating the gate insulating film tunnel current using a third model having no temperature dependency provided between the gate and the source and a fourth model having no temperature dependency provided between the gate and the drain.

In order to achieve yet still another aspect of the present invention, a MOSFET simulation method using a new MOSFET model, is attained by when a voltage of a gate of a MOSFET model known as BSIM3V3 is higher than voltages of a source and drain, respectively, simulating a gate insulating film tunnel current using a first model having bias dependency provided between the gate and a source and a second model having bias dependency provided between the gate and a drain; and by when the voltage of the gate is lower than the voltages of the source and drain, respectively, simulating the gate insulating film tunnel current using a third model having bias dependency provided between the gate and the source and a fourth model having bias dependency provided between the gate and the drain.

### BRIEF DESCRIPTION OF THE DRAWINGS

FIGS. 1A and 1B are circuit diagrams showing gate oxide film tunnel current models of MOSFETs according to an embodiment of the present invention, respectively;

FIG. 2 is a diagram showing an equivalent circuit of a diode according to the embodiment of the present invention;

FIG. 3 is a diagram showing gate voltage-gate current characteristic of the MOSFET and an approximation characteristic of the tunnel current model according to the embodiment of the present invention;

FIG. 4 is a perspective view of a MOSFET; and

FIG. 5 is a block diagram showing the structure of a MOSFET simulation apparatus according to the embodiment of the present invention.

### DESCRIPTION OF THE PREFERRED EMBODIMENTS

Next, a gate oxide film tunnel current model of the present invention will be described below in detail with reference to the attached drawings.

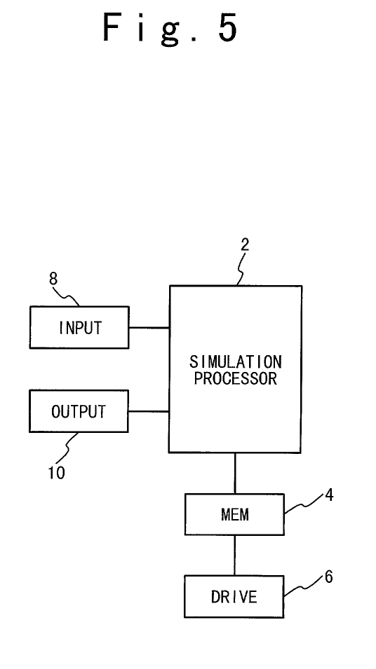

FIG. 5 is a block diagram showing the structure of a MOSFET simulation apparatus according to the embodiment of the present invention. Referring to FIG. 5, the MOSFET simulation apparatus is composed of a simulation processor 2, a memory 4, a recoding medium drive 6, an input unit 8 and an output unit 10. The simulation processor 2 carries out a simulation based on a program stored in the memory 4 by reading a recording medium (not shown) by the drive 6. The simulation processor 2 outputs the simulation result to the output unit 10. The input unit 8 is used to input an instruction or data.

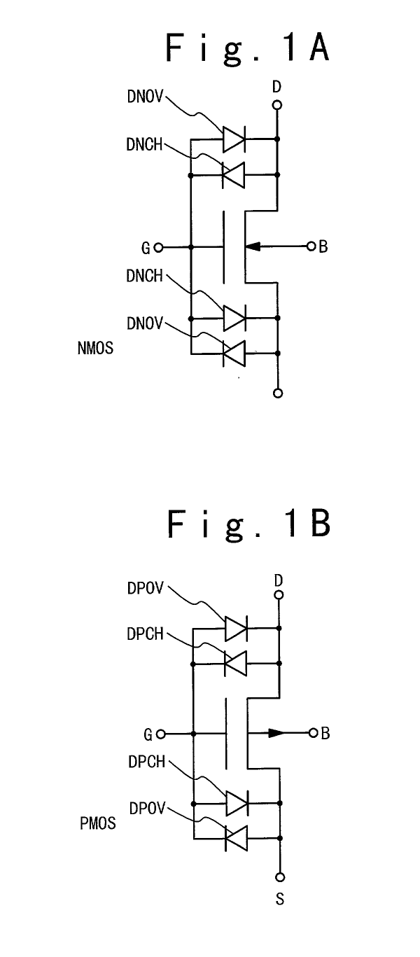

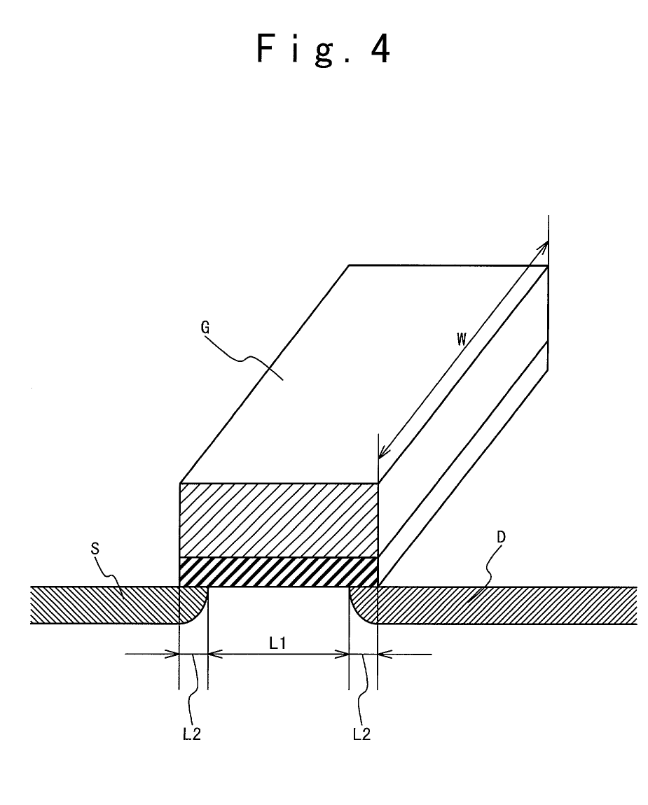

Next, FIG. 1 is a circuit diagram showing the structure of a gate oxide film tunnel current model according to an embodiment of the present invention. The gate oxide film tunnel current model is composed of a first portion which is connected between the gate and the drain in a usual MOSFET circuit model as known as BSIM3V3, and a second portion which is connected between the gate and the source in the usual MOSFET circuit model. Each of the first and second portions of the gate oxide film tunnel current model is composed of two diodes whose area and characteristic are different from each other. These diodes are connected in parallel in opposite directions. That is, FIG. 1A shows an example of an N-type MOSFET. A diode DNCH is used to express a tunnel current between the channel and the gate electrode of the N-type MOSFET. A diode DNOV is used to express the tunnel current between the gate electrode and an overlapping area between the source/drain. The diode DNCH and the diode DNOV are connected in parallel in opposite directions. The first portion is connected between a gate G and a drain D and the second portion is connected between the gate G and a source S. The diode DNCH has an area of half of a gate area. The diode DNOV has an area obtained by multiplying the gate width W (FIG. 4) by the overlapping length L2 of the gate and the source/drain diffusion layer.

Also, FIG. 1B shows an example of a P-type MOSFET. A diode DPCH shows a tunnel current between the channel and the gate electrode in the P-type MOSFET. A diode DPOV shows tunnel current between the gate electrode and the overlapping area between the source/drain and the gate. The diode DPCH and the diode DPOV are connected in parallel in opposite directions. The first portion is connected between a gate G and a drain D and the second portion is connected between the gate G and a source S. The diode DPCH has an area of half of a gate area. The diode DPOV has an area obtained by multiplying the gate width W (FIG. 4) by the overlapping length L2 of the gate and the source/drain diffusion layer.

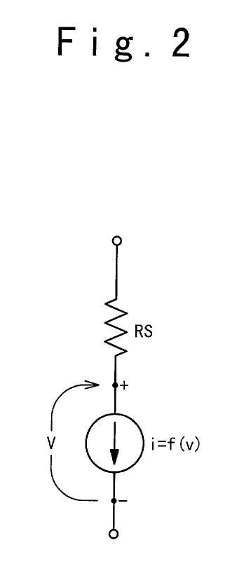

FIG. 2 shows an equivalent circuit model of each of the diodes DNCH, DPCH, and DNOV and DPOV. As shown in FIG. 2, the equivalent circuit model is composed of a series resistance RS and a voltage controlled current source i [=f(v)]. The equivalent circuit model does not have a capacitance component. The characteristic of the voltage controlled current source i is expressed by the equation (1), for example:

$$i = Is [ exp ( \frac{V}{{N}_{FT}} ) - 1 ] \qquad ( 1 )$$

where Is is a source current, V is a voltage applied between the voltage controlled current source, N_{FT} is a parameter which shows bias dependence of the tunnel current. Also, each of the parameters RS, Is, NFT in the equivalent circuit model of the diode do not have temperature dependence.

Next, the operation of the tunnel current model of the present invention will be described. For example, in case of the N-type MOSFET of FIG. 1A, the operation of a source side region and a drain side region based on the structure symmetry will be described.

(1) The source side

1: In case of Vg (gate voltage)>Vs (source voltage):

The tunnel current which flows from the gate to the channel is primary. The bias dependence of the tunnel current can be approximated based on the diode model DNCH which is connected with the gate on the anode side and the source on the cathode side, and has the series resistance. Also, because the area of diode model DNCH is the half of the gate area, the approximation is possible supposing that the magnitude of the tunnel current is proportional to 1/2 of the gate area.

(2) In case of Vg<Vs

The tunnel current which flows from the overlapping region between the source and the gate to the gate is primary. The bias dependence of this tunnel current is possible to approximate by the diode model DNOV which has a series resistance and which is connected with the source on the anode side and is connected with the gate on the cathode side. Also, the magnitude of the tunnel current is possible to approximate to be proportional to the area obtained by multiplying the gate width W by the overlapping length L2 between the source and the gate, because the area of the diode model DNOV is equal to an area obtained by multiplying the gate width by the overlapping length between the source and the gate.

(2) The drain side

1: In case of Vg>Vd:

The tunnel current which flows from the gate to the channel is primary. The bias dependence of this tunnel current is possible to approximate by the diode model DNCH which has a series resistance and which is connected with the gate on the anode side and is connected with the drain on the cathode side. Also, the magnitude of the tunnel current is possible to approximate to be proportional to 1/2 of the gate area.

2: In case of Vg<Vd:

The tunnel current which flows from the overlapping region between the drain and the gate to the gate is primary. The bias dependence of this tunnel current is possible to approximate by the diode model DNOV which has a series resistance and which is connected with the drain on the anode side and is connected with the gate on the cathode side. Also, the magnitude of the tunnel current is possible to approximate to be proportional to the area obtained by multiplying the gate width by the overlap length between the drain and the gate.

It should be noted that the approximation is similar in the P-type MOSFET shown in FIG. 1B. The bias dependence of the tunnel current and the magnitude of each of the tunnel currents in the cases of Vg>Vs, Vg>Vd and Vg<Vs, and Vg<Vd on the source side and the drain side is possible to approximate by the diode models DPCH and DPOV.

As above mentioned, in the present invention, the standard MOSFET model in which the gate oxide film tunnel current is not considered, and the standard diode models are used, as shown in FIGS. 1A and 1B. Therefore, the tunnel current between the gate and the drain and between the gate and the source in the MOSFET are conspicuous in the range in which the gate oxide film thickness is equal to or less than 2 nm. Such tunnel current can be relatively precisely expressed by reflecting the relative potential change between the gate and the drain and between the gate and the source.

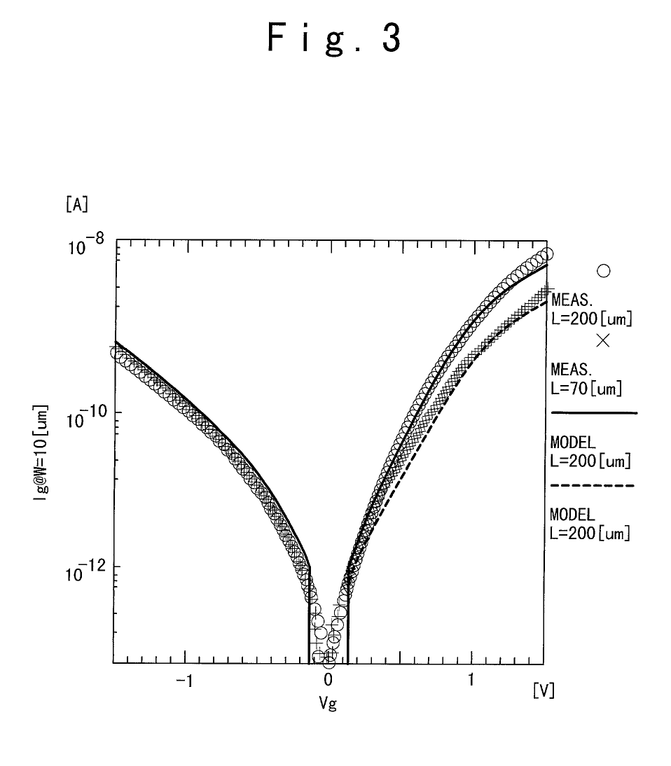

For example, as shown in FIG. 3, it is supposed that the source, the drain, and the substrates of the N-type MOSFET are all connected to the ground potential. Also, it is supposed that a positive voltage is applied to the gate. In this case, the gate leak current is proportional to the gate length. Also, the gate leak current when a negative voltage is applied to the gate does not depend on the gate length and takes an approximately constant value. In the diode models, it could be found that this state can be reproduced in a good precision.

Also, the asymmetry of the gate length dependence of the leak current in the same figure is brought about due to the following causes. The tunnel current which flows from the gate to the channel is proportional to the gate area while the tunnel current which flows from the channel to the gate is proportional to the area of the overlapping area between the gate and the source/drain diffusion layer. Also, the overlapping length changes hardly even if the channel length changes. Also, in the diode models, the two diodes which are different in area and characteristic from each other are connected in parallel and in opposing directions to produce a parallel connection. The parallel connections are connected between the gate and the drain and between the gate and the source in the usual transistor circuit model, respectively. Therefore, the asymmetry of the gate length dependence of this leak current can be reproduced.

Further, the diode model does not have a capacitance component, as shown in the equivalent circuit of FIG. 2. Therefore, the diode model never overlaps the capacitance model which is contained in the standard MOSFET model. Thus, a right result can be obtained in case of transient analysis. Also, the respective parameters RS, Is, and N_{FT} of the diode model do not have temperature dependence. Therefore, the characteristic of the tunnel current that there is little temperature dependence can be reproduced in a good precision.

As described above, in the gate oxide film tunnel current model of the present invention, two kinds of diodes with different areas and different characteristics are connected in parallel in the opposite directions. The parallel circuit is connected between the gate and the drain and between the gate and the source in the MOS transistor circuit model. Therefore, the tunnel current between the gate and the drain and between the gate and the source in the MOSFET with the film thickness of the gate oxide film equal to or less than 2 nm becomes conspicuous. Such tunnel current can be expressed in a relatively good precision by reflecting a relative potential change between the gate and the drain and between the gate and the source.

Also, in the gate oxide film tunnel current model of the present invention, the diode equivalent circuit is composed of series resistance and a voltage controlled current source. Also, the diode equivalent circuit does not have a capacitance component. Therefore, a right result can be obtained in case of transient analysis. Further, each of the parameters of the diode model does not have temperature dependence. Therefore, the characteristic of the tunnel current that there is little temperature dependence can be reproduced in a good precision.

Therefore, according to the present invention, it is possible to simulate the tunnel current between the gate and the source and between the gate and the drain in the MOSFET. Also, it is possible to reproduce the transient characteristic, and the temperature non-dependence of the MOSFET.

What is claimed is:

1. A MOSFET simulation apparatus comprising:
an output unit; and
a processor which simulates an operation of MOSFET using a new MOSFET model, and outputs the simulation result to said output unit,
wherein said new MOSFET model comprises:
a MOSFET model known as BSIM3V3 and having a gate, a source, a drain and a gate insulating film;
a first circuit model connected between said gate and said source, and including first and second diode models connected in parallel in opposite directions to each other; and
a second circuit model connected between said gate and said drain, and including third and fourth diode models connected in parallel in opposite directions to each other.

2. The MOSFET simulation apparatus according to claim 1, wherein said gate insulating film is equal to or thinner than 2 nm.

3. The MOSFET simulation apparatus according to claim 1, wherein each of said first to fourth diode models does not depend on temperature.

4. The MOSFET simulation apparatus according to claim 3, wherein each of said first to fourth diode models includes a series connection of a resistance model and a voltage controlled current source without a capacitance model.

5. The MOSFET simulation apparatus according to claim 4, wherein said voltage controlled current source is expressed by
$$i = Is [ exp ( \frac{V}{{N}_{FT}} ) - 1 ]$$
where i is current, N_{FT} is a bias-dependence parameter of tunnel current, V is a voltage applied to said voltage controlled current source, and Is is source current.

6. The MOSFET simulation apparatus according to claim 1, wherein said first diode model has an anode connected to said gate and a cathode connected to said source and said third diode models has an anode connected to said gate and a cathode connected to said drain, and said first and third diode models are used when a voltage of said gate is higher than voltages of said source and said drain, respectively.

7. The MOSFET simulation apparatus according to claim 6, wherein each of said first and third diode models has an area equal to a half of an area of said gate.

8. The MOSFET simulation apparatus according to claim 1, wherein said second diode model has an anode connected to said source and a cathode connected to said gate and said fourth diode models has an anode connected to said drain and a cathode connected to said gate, and said second and fourth diode models are used when a voltage of said gate is lower than voltages of said source and said drain, respectively.

9. The MOSFET simulation apparatus according to claim 8, wherein said second diode model has an area equal to an overlapping area of said gate and said source, and said fourth diode model has an area equal to an overlapping area of said gate and said drain.

10. A recording medium in which a program is recorded for a MOSFET simulation method using a new MOSFET model, wherein said new MOSFET model comprises:
a MOSFET model known as BSIM3V3 and having a gate, a source, a drain and a gate insulating film;
a first circuit model connected between said gate and said source, and including first and second diode models connected in parallel in opposite directions to each other; and
a second circuit model connected between said gate and said drain, and including third and fourth diode models connected in parallel in opposite directions to each other.

11. The recording medium according to claim 10, wherein said gate insulating film is equal to or thinner than 2 nm.

12. The recording medium according to claim 10, wherein each of said first to fourth diode models does not depend on temperature.

13. The recording medium according to claim 12, wherein each of said first to fourth diode models includes a series connection of a resistance model and a voltage controlled current source without a capacitance model.

14. The recording medium according to claim 13, wherein said voltage controlled current source is expressed by
$$i = Is [ exp ( \frac{V}{{N}_{FT}} ) - 1 ]$$
where i is current, N_{FT} is a bias-dependent parameter of tunnel current, V is a voltage applied to said voltage controlled current source, and Is is source current.

15. The recording medium according to claim 10, wherein said first diode model has an anode connected to said gate and a cathode connected to said source and said third diode models has an anode connected to said gate and a cathode connected to said drain, and said first and third diode models are used when a voltage of said gate is higher than voltages of said source and said drain, respectively.

16. The recording medium according to claim 15, wherein each of said first and third diode models has an area equal to a half of an area of said gate.

17. The recording medium according to claim 10, wherein said second diode model has an anode connected to said source and a cathode connected to said gate and said fourth diode models has an anode connected to said drain and a cathode connected to said gate, and said second and fourth diode models are used when a voltage of said gate is lower than voltages of said source and said drain, respectively.

18. The recording medium according to claim 17, wherein said second diode model has an area equal to an overlapping area of said gate and said source, and said fourth diode model has an area equal to an overlapping area of said gate and said drain.

19. A MOSFET simulation method using a new MOSFET model, comprising:
when a voltage of a gate of a MOSFET model known as BSIM3V3 is higher than voltages of a source and drain, respectively, simulating a gate insulating film tunnel current using a first model having no temperature dependency provided between said gate and a source and a second model having no temperature dependency provided between said gate and a drain; and
when the voltage of said gate is lower than the voltages of said source and drain, respectively, simulating said gate insulating film tunnel current using a third model having no temperature dependency provided between said gate and said source and a fourth model having no temperature dependency provided between said gate and said drain.

20. A MOSFET simulation method using a new MOSFET model, comprising:
when a voltage of a gate of a MOSFET model known as BSIM3V3 is higher than voltages of a source and drain, respectively, simulating a gate insulating film tunnel current using a first model having bias dependency provided between said gate and a source and a second model having bias dependency provided between said gate and a drain; and
when the voltage of said gate is lower than the voltages of said source and drain, respectively, simulating said gate insulating film tunnel current using a third model having bias dependency provided between said gate and said source and a fourth model having bias dependency provided between said gate and said drain.
